(19) United States
(12) Patent Application Publication
(10) Pub. No.: US 2026/0241815 A1
(43) Pub. Date: Aug. 20, 2026

(54) DRIVING APPARATUS FOR AN ELECTRIC VEHICLE HAVING A MOTOR WITH A THREE-PHASE COIL, A POWER STORAGE DEVICE AND AN INVERTER, WHICH IS CONFIGURED TO BE OPERATED IN A THREE-PHASE MODE AND A TWO-PHASE MODE

(71) Applicant: TOYOTA JIDOSHA KABUSHIKI KAISHA, Toyota-shi, Aichi-ken (JP)

(72) Inventors: Mitsutaka ITO, Nisshin-shi (JP); Kazuhiro SUGIMOTO, Toyota-shi (JP)

(73) Assignee: TOYOTA JIDOSHA KABUSHIKI KAISHA, Toyota-shi, Aichi-ken (JP)

(21) Appl. No.: 19/161,906

(22) PCT Filed: Feb. 26, 2024
(86) PCT No.: PCT/JP2024/006706

§ 371 Date: Sep. 3, 2025

(30) Foreign Application Priority Data
Mar. 10, 2023 (JP) 2023-037654

(51) Int. Cl. B60L 53/24; H05K 7/20

(52) U.S. Cl. CPC B60L 53/24; H05K 7/20872; B60L 2210/40; B60L 2270/44

(57) ABSTRACT

A driving apparatus includes a motor with a three-phase coil, a power storage device, and an inverter configured to convert direct current power from the power storage device into three-phase alternating current power and to supply the three-phase alternating current power to the motor. The driving apparatus is programmed to perform a first mode of driving all three phases of the inverter, or a second mode of driving two of the three phases of the inverter, during at least one of external charging, in which power supplied from an external power source device to a neutral point to which the three-phase coil is connected is supplied to the power storage device with voltage conversion by the motor and the inverter, and external power supply, in which power from the power storage device is supplied to the outside of the driving apparatus via the neutral point with voltage conversion by the inverter and the motor.

### TECHNICAL FIELD

The present disclosure relates to a driving apparatus.

### BACKGROUND ART

A proposed configuration of a driving apparatus includes a motor with a three-phase coil, a power storage device, and an inverter that converts direct current power from the storage device into three-phase alternating current power and supplies it to the motor (see, for example, Patent Documents 1 and 2). The driving apparatus of Patent Document 1 controls the inverter by setting a duty value of switching elements of the inverter during external charging, in which power supplied from an external power source device to the neutral point to which the three-phase coil is connected is supplied to the power storage device with voltage conversion by the motor and the inverter. The driving apparatus of Patent Document 2 also controls the inverter by setting one of three-phase currents of the motor to zero based on the rotor angle of the motor and the remaining two-phase currents to make a torque of the motor zero during external charging.

### CITATION LIST

### Patent Literature

[PTL 1] US2020/0177014
[PTL 2] US2020/0189409

### SUMMARY OF INVENTION

### Technical Problem

In the driving apparatus, the heating value of the motor tends to be large, in the case where the driving apparatus always performs the first mode which drives all three phases of the inverter, as in Patent Documents 1, during at least one of the external charging and external power supply in which power from the power storage device is supplied to the outside of the driving apparatus via the neutral point of the motor with voltage conversion by the inverter and the motor. On the other hand, in the driving apparatus, the heating value of the inverter tends to be large, in the case where the driving apparatus always performs the second mode which drives two of the three phases of the inverter, as in Patent Documents 2, during at least one of the external charging and the external power supply. Based on these considerations, there is a need to perform at least one of the external charging and the external power supply more appropriately.

A main object of the driving apparatus of the present disclosure is to perform at least one of the external charging and the external power supply more appropriately.

### Solution to Problem

In order to achieve the above main object, the driving apparatus of the present disclosure employs the following configuration.

The driving apparatus of the present disclosure includes a motor with a three-phase coil, a power storage device, and an inverter configured to convert direct current power from the power storage device into three-phase alternating current power and to supply the three-phase alternating current power to the motor. The driving apparatus is programmed to perform the first mode of driving all three phases of the inverter, or the second mode of driving two of the three phases of the inverter, during at least one of external charging, in which power supplied from an external power source device to the neutral point to which the three-phase coil is connected is supplied to the power storage device with voltage conversion by the motor and the inverter, and external power supply, in which power from the power storage device is supplied to the outside of the driving apparatus via the neutral point with voltage conversion by the inverter and the motor.

The driving apparatus of the present disclosure performs the first mode of driving all three phases of the inverter, or the second mode of driving two of the three phases of the inverter, during at least one of external charging, in which power supplied from an external power source device to the neutral point to which the three-phase coil is connected is supplied to the power storage device with voltage conversion by the motor and the inverter, and external power supply, in which power from the power storage device is supplied to the outside of the driving apparatus via the neutral point with voltage conversion by the inverter and the motor. This configuration enables at least one of the external charging and the external power supply to be more appropriately performed.

In the driving apparatus of the present disclosure, the driving apparatus may be configured to perform the first mode or the second mode based on at least one of information related to the motor, information related to the inverter, information related to the power storage device, information related to the neutral point, and information related to the external environment. Thus, the driving apparatus can perform the first mode or the second mode based on at least one of the various types of information. The information related to the motor includes a temperature of the motor. The information related to the inverter includes a temperature of the inverter. The information related to the power storage device includes a temperature of the power storage device. The information related to the neutral point includes a power and current from the external power source device to the neutral point. The information related to the external environment includes presence or absence of a heating demand and a temperature in a cabin of a vehicle when the driving apparatus includes a heater that uses the motor and the inverter as a heat source to heat the cabin.

In the driving apparatus of the above aspect which performs the first mode or the second mode based on at least one of the various types of information, the driving apparatus may be programmed to perform the interleaved driving in the second mode when a supply-related value relating to the power or the current supplied to the neutral point from the external power source device is equal to or less than a supply threshold value, and to perform the interleaved driving in the first mode when the supply-related value is greater than the supply threshold value. In the interleaved driving in the first mode, the inverter is driven such that phases of the three-phase currents of the motor are shifted 120 degrees from each other. For example, in the interleaved driving in the first mode, the phases of the three-phase currents of the motor may be shifted 120 degrees from each other by shifting the phases of carriers (e.g., triangular waves, sawtooth waves, inverse sawtooth waves, etc.) of each phase in duty control of the switching elements of the three phases of the inverter by 120 degrees from each other. In the interleaved driving in the second mode, the inverter is driven such that the phases of the two-phase currents of the motor are shifted by 180 degrees from each other. For example, in the interleaved driving in the second mode, the phases of the two-phase currents of the motor may be shifted by 180 degrees from each other by shifting the phases of the carriers of each phase in the duty control of the switching elements of the two phases of the inverter by 180 degrees from each other. The inventors confirmed the following through experimentation, analysis, and machine learning. In a case where the supply-related value is small, a heating value of the entire driving section, including the motor and the inverter, is larger and efficiency of the external charging is lower when the interleaved driving is performed in the first mode than when the interleaved driving is performed in the second mode. On the other hand, in a case where the supply-related value is high, the heating value of the entire driving section is larger and the efficiency of the external charging is lower when the interleaved driving is performed in the second mode, compared to when the interleaved driving is performed in the first mode. Based on this, the driving apparatus performs the interleaved driving in the second mode when the supply-related value is equal to or less than the supply threshold value, and performs the interleaved driving in the first mode when the supply-related value is greater than the supply threshold value. This configuration suppresses the heating value of the entire driving section. As a result, the efficient external charging is possible.

In the driving apparatus of the above aspect which performs the interleaved driving in the first mode or the second mode based on the supply-related values, the driving apparatus may further include a cooler configured to circulate a cooling medium to the motor, the inverter, and the power storage device. The driving apparatus may be programmed to perform the interleaved driving in the first mode when a temperature rise of the power storage device is requested and the supply-related value is less than the supply threshold value, and the driving apparatus may be programmed to perform the interleaved driving in the second mode when the temperature rise of the power storage device is requested and the supply-related value is equal to or greater than the supply threshold value. This configuration increases the heating value of the entire driving section. As a result, the temperature rise of the power storage device is accelerated.

In the driving apparatus of the above aspect which performs the interleaved driving in the first mode or the second mode based on the supply-related values, the driving apparatus may further include a heater configured to use the motor and the inverter as a heat source to heat a cabin of the vehicle. The driving apparatus may be programmed to perform the interleaved driving in the first mode when heating in the cabin is requested and the supply-related value is less than the supply threshold value, and the driving apparatus may be programmed to perform the interleaved driving in the second mode when the heating in the cabin is requested and the supply-related value is equal to or greater than the supply threshold value. This configuration increases the heating value of the entire driving section. As a result, the cabin is heated more adequately.

In the driving apparatus of the above aspect which performs the first mode or the second mode based on at least one of the various types of information, the driving apparatus may be programmed to perform the interleaved driving in the first mode when a temperature of the inverter is greater than a second temperature threshold value. This configuration suppresses further temperature rise of the inverter.

In the driving apparatus of the above aspect which performs the first mode or the second mode based on at least one of the various types of information, the driving apparatus may be programmed to perform the interleaved driving in the first mode when a temperature of the motor is greater than a first temperature threshold value and a temperature of the inverter is greater than a second temperature threshold value and the inverter is thermally more severe than the motor. This configuration suppresses further temperature rise of the inverter when the inverter is thermally more severe than the motor.

In the driving apparatus of the above aspect which performs the first mode or the second mode based on at least one of the various types of information, the driving apparatus may be programmed to instruct the external power source device to limit the power or current from the external power source device to the neutral point when a temperature of the motor is greater than a first temperature threshold value and/or a temperature of the inverter is greater than a second temperature threshold value, compared to when the temperature of the motor is equal to or less than the first temperature threshold value and the temperature of the inverter is equal to or less than the second temperature threshold value. This configuration suppresses further temperature rise of the motor and the inverter when the temperature of the motor is greater than the first temperature threshold value and/or the temperature of the inverter is greater than the second temperature threshold value.

In the driving apparatus of the present disclosure, the driving apparatus may be programmed to perform the interleaved driving in the first mode or the second mode, and the driving apparatus may be programmed to perform the interleaved driving using two driving phases, which are the two phases with the smallest discrepancy in inductance values among the three phases, in the second mode. This configuration suppresses the heating value of the motor when the interleaved driving is performed in the second mode. As a result, the efficient external charging is possible.

In the driving apparatus of the above aspect which performs interleaved driving using the two driving phases in the second mode, the driving apparatus may further include a cooler configured to circulate a cooling medium to the motor, the inverter, and the power storage device. The driving apparatus may be programmed to perform the interleaved driving using the two driving phases, which are the two phases with the largest discrepancy in the inductance values among the three phases, in the second mode when a temperature rise of the power storage device is requested. This configuration increases the heating value of the motor when the interleaved driving is performed in the second mode. As a result, the temperature rise of the power storage device is accelerated.

In the driving apparatus of the above aspect which performs interleaved driving using the two driving phases in the second mode, the driving apparatus may further include a heater configured to use the motor and the inverter as a heat source to heat a cabin of the vehicle. The driving apparatus may be programmed to perform the interleaved driving using the two driving phases, which are the two phases with the largest discrepancy in the inductance values among the three phases, in the second mode when heating in the cabin is requested. This configuration increases the heating value of the motor when the interleaved driving is performed in the second mode. As a result, the cabin is heated more adequately.

In the driving apparatus of the above aspect which performs interleaved driving using the two driving phases in the second mode, the driving apparatus may be programmed to set the two driving phases based on a rotational position of a rotor of the motor. This configuration sets the two driving phases more appropriately.

In the driving apparatus of the above aspect which performs interleaved driving using the two driving phases in the second mode, the driving apparatus may be programmed to set the two driving phases based on an amount of change per unit time in a phase current of each phase of the motor when a test current flows to each phase of the motor. This configuration more appropriately sets the two driving phases.

In the driving apparatus of the present disclosure, the driving apparatus may be programmed to set a target voltage ratio based on which one of the first mode and the second mode is selected, and to instruct the external power source device to apply a target voltage based on a voltage of the power storage device and the target voltage ratio to the neutral point from the external power source device. This configuration enables the external charging to be performed with the voltage conversion by the motor and the inverter at a voltage ratio depending on whether the first mode or the second mode is selected. The voltage ratio is defined as a ratio between the voltage at the neutral point and the voltage of the power storage device.

In the driving apparatus of the above aspect which sets the target voltage ratio based on whether the first mode or the second mode is selected, the driving apparatus may further include a cooler configured to circulate a cooling medium to the motor, the inverter, and the power storage device. The driving apparatus may be programmed to set the target voltage ratio based on which one of the first mode and the second mode is selected and whether or not temperature rise of the power storage device is requested. This configuration sets the target voltage ratio more appropriately.

In the driving apparatus of the above aspect which sets the target voltage ratio based on whether the first mode or the second mode is selected, the driving apparatus may further include a heater configured to use the motor and the inverter as a heat source to heat a cabin of the vehicle. The driving apparatus may be programmed to set the target voltage ratio based on which one of the first mode and the second mode is selected and whether or not heating in the cabin is requested. This configuration sets the target voltage ratio more appropriately.

### BRIEF DESCRIPTION OF DRAWINGS

FIG. 1 is a schematic configuration diagram of a driving apparatus and a charging stand.

FIG. 2 is a schematic configuration diagram of the driving apparatus and the charging stand.

FIG. 3 is a flowchart showing one example of an external charging control routine.

FIG. 4 is a diagram showing one example of the phase currents of each phase of a motor.

FIG. 5 is a diagram showing one example of the relationship between an electric angle of the motor and an inductance value of each phase of the motor.

FIG. 6 is a flowchart showing one example of the first sub-processing.

FIG. 7 is a flowchart showing one example of the second sub-processing.

FIG. 8 is a diagram showing one example of the relationship between a voltage ratio of a multiphase boost converter and a ripple of the phase current of each phase of the motor.

FIG. 9 is a flowchart showing one example of an external charging control routine of another modification.

FIG. 10 is a flowchart showing one example of the third sub-processing.

FIG. 11 is a flowchart showing one example of the third sub-processing.

FIG. 12 is a schematic configuration diagram of a driving apparatus.

### DESCRIPTION OF EMBODIMENTS

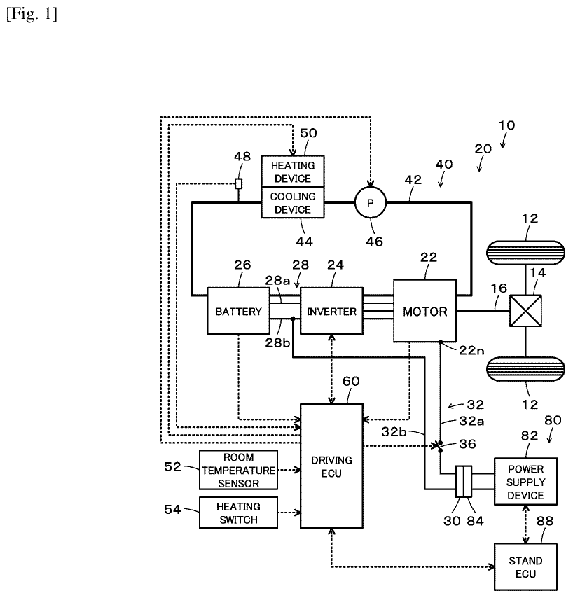

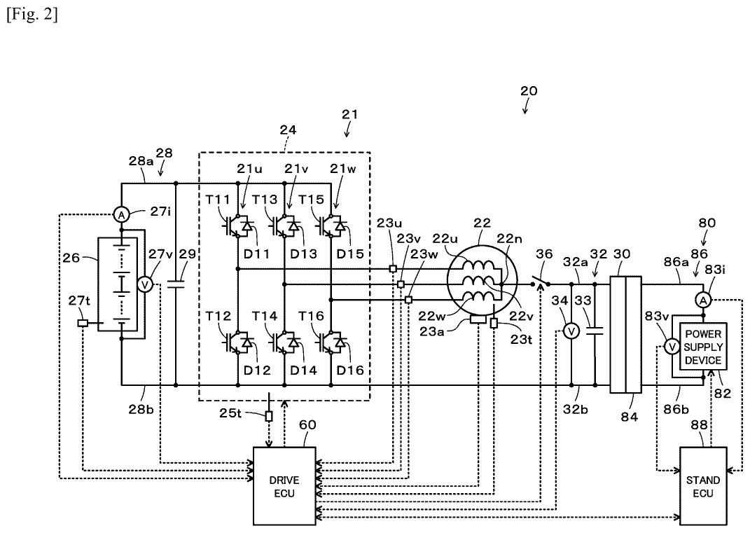

An embodiment of the present disclosure is described below with reference to drawings. FIG. 1 and FIG. 2 are schematic configuration diagrams of a driving apparatus 20 of the embodiment mounted on a battery electric vehicle 10 and a charging stand 80, which is one example of an external power source device. As shown in FIG. 1 and FIG. 2, the driving apparatus 20 includes a motor 22, an inverter 24, a battery 26, which is one example of a power storage device, a apparatus side connector 30, a switch 36, a cooler 40, a heater 50, and a driving electronic control unit (hereinafter referred to as “driving ECU”) 60, which is one example of a controller.

The motor 22 is configured as a three-phase AC motor and includes a rotor with permanent magnets embedded in a rotor core and a stator with U, V and W phase coils 22u, 22v and 22w, respectively, wound on a stator core. The connection of the U, V and W phase coils 22u, 22v and 22w forms the neutral point 22n. The rotor of the motor 22 is connected to the drive shaft 16, which is connected to drive wheels 12 via a differential gear 14.

The inverter 24 is used to drive the motor 22 and is connected to the battery 26 via a positive side line 28a and a negative side line 28b of a power line 28. The inverter 24 includes six transistors T11 to T16, which are one example of six switching elements, and six diodes D11 to D16. The transistors T11 to T16 are arranged in pairs so as to the source side and sink side of the positive side line 28a and the negative side line 28b, respectively. A connection point of the transistors T11 and T12, a connection point of the transistors T13 and T14, and a connection point of the transistors T15 and T16 are connected to the U, V and W phase coils 22u, 22v and 22w of the motor 22, respectively. The six diodes D11 to D16 are connected in parallel with the six transistors T11 to T16, respectively. The inverter 24 converts direct current power from the battery 26 into three-phase alternating current power by pulse width modulation control (PWM control) and supplies the three-phase alternating current power to the motor 22. A capacitor 29 is connected to the positive side line 28a and the negative side line 28b.

The battery 26 includes a plurality of battery cells, each of which is configured as a lithium ion rechargeable battery and connected in series with one another. The battery 26 is connected to the inverter 24 via the positive side line 28a and the negative side line 28b, as described above.

The apparatus side connector 30 is configured to be connected to the stand side connector 84 of the charging stand 80. The apparatus side connector 30 is connected to the neutral point 22n of the motor 22 via the positive side line 32a of the power line 32 and the switch 36, and to the negative side line 28b via the negative side line 32b of the power line 32. A capacitor 33 is connected to the positive side line 32a and the negative side line 32b. The switch 36 connects and disconnects the positive side line 32a with the neutral point 22n of the motor 22 by turning it on and off.

A multiphase boost converter 21 is configured by the motor 22 and the inverter 24 between the positive side line 32a and the negative side line 32b of the power line 32 and the positive side line 28a and the negative side line 28b of the power line 28, when the switch 36 is turned on. The multiphase boost converter 21 includes three-phase (U, V and W) voltage conversion sections 21u, 21v and 21w connected in parallel with each other to the power line 32 and the power line 28. The U phase voltage conversion section 21u includes the U phase coil 22u of the motor 22 and the transistors T11 and T12 of the inverter 24. The V phase voltage conversion section 21v includes the V phase coil 22v of the motor 22 and the transistors T13 and T14 of the inverter 24. The W phase voltage conversion section 21w includes the W phase coil 22w of the motor 22 and the transistors T15 and T16 of the inverter 24.

The cooler 40 includes a circulating flow path 42, a heat exchanger 44, and an electric pump 46. The circulating flow path 42 is configured as a flow path for circulating cooling water to the motor 22, the inverter 24, the battery 26, and the heat exchanger 44 in that order. The electric pump 46 circulates the cooling water in the circulating flow path 42. The circulating flow path 42 may be configured to circulate the cooling water to the inverter 24, the motor 22, the battery 26, and the heat exchanger 44 in that order.

The heater 50 uses the cooling water of the cooler 40 (the cooling water heated by the motor 22 and the inverter 24) as a heat source caused by to heat a cabin of the vehicle. The heater 50 includes a blower that blows air heated by heat exchange with the heat exchanger 44 into the cabin.

The driving ECU 60 includes a microcomputer, which has a CPU, ROM, RAM, flash memory, input/output ports, and communication ports. The driving ECU 60 inputs signals from various sensors. For example, the driving ECU 60 inputs a rotational position Om of the rotor of the motor 22 from a rotational position sensor 23a, U, V and W phase currents Iu, Iv and Iw of the motor 22 from current sensors 23u, 23v and 23w, a temperature am of the motor 22 from a temperature sensor 23t, and a temperature ai of the inverter 24 from a temperature sensor 25t. The driving ECU 60 also inputs a voltage Vb of the battery 26 from a voltage sensor 27v, a current Ib of the battery 26 from a current sensor 27i, and a temperature ab of the battery 26 from a temperature sensor 27t. The driving ECU 60 also inputs a voltage VL of the capacitor 33 (the power line 32) from a voltage sensor 34 and a cooling water temperature aw, which is a temperature of the cooling water in the circulating flow path 42, from a water temperature sensor 48. The driving ECU 60 also inputs a room temperature ac, which is a temperature in the cabin from a room temperature sensor 52, and whether or not a heating in the cabin is requested and a set temperature αcset in the cabin from a heating switch 54.

The driving ECU 60 outputs various control signals. For example, the driving ECU 60 outputs control signals to the transistors T11 and T16 of the inverter 24, the switch 36, the electric pump 46, and the heater 50. The driving ECU 60 calculates the electric angle Oe and the rotational speed Nm of the motor 22 based on the rotational position Om of the rotor of the motor 22. The driving ECU 60 calculates the state of charge SOC of the battery 26 based on the integrated value of the current Ib of the battery 26. The driving ECU 60 sets the input limit Win, which is the allowable input power of the battery 26, based on the state of charge SOC of the battery 26 and the temperature ab of the battery 26. The driving ECU 60 is capable of communicating with the electronic control unit 88 (hereinafter referred to as “stand ECU”) of the charging stand 80 (hereinafter referred to as “stand ECU”) at home or at a charging station.

The charging stand 80 is located at homes and charging stations and so on. The charging stand 80 includes a power supply device 82, the stand side connector 84, and the stand ECU 88. The power supply device 82 is connected to the stand side connector 84 via the positive side line 86a and the negative side line 86b of the power line 86. The power supply device 82 is configured to convert alternating current power from a power system to direct current power and to adjust output voltage and output power. The stand side connector 84 is configured to be connected to the apparatus side connector 30 of the driving apparatus 20. When the stand side connector 84 is connected to the apparatus side connector 30, the positive side line 86a is connected to the positive side line 32a, and the negative side line 86b is connected to the negative side line 32b, respectively.

The stand ECU 88 includes a microcomputer, which has a CPU, ROM, RAM, flash memory, input/output ports, and communication ports. The stand ECU 88 inputs an output voltage Vs of the power supply device 82 from a voltage sensor 83v and an output current Is of the power supply device 82 from a current sensor 83i. The stand ECU 88 outputs a control signal to the power supply device 82. The stand ECU 88 calculates an output power Ps based on the output voltage Vs and the output current Is. The stand ECU 88 is capable of communicating with the driving ECU 60 of the driving apparatus 20.

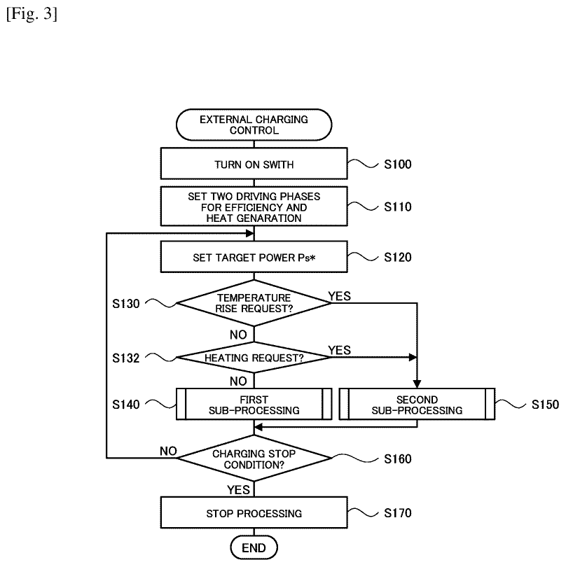

The following describes the operation of the driving apparatus 20, in particular the operation during the external charging. The external charging is charging of the battery 26 using power from the power supply device 82 of the charging stand 80. In the external charging, the neutral power supplied by the power supply device 82 to the neutral point 22n of the motor 22 is supplied to the battery 26 with voltage conversion by the multiphase boost converter 21 (the motor 22 and the inverter 24). FIG. 3 is a flowchart showing one example of an external charging control routine performed by the driving ECU 60. This routine is performed when the apparatus side connector 30 of the driving apparatus 20 is connected to the stand side connector 84 of the charging stand 80 and the charging start condition is satisfied. The charging start condition is, for example, an OR condition, such as a condition in which the user instructs to start charging the battery 26, or a condition in which the charging start time of the battery 26 set by the user has been reached, and so on.

In the external charging control routine shown in FIG. 3, the driving ECU 60 first turns on the switch 36 (step S100). This connects the neutral point 22n of the motor 22 to the positive side line 32a. Thus, as described above, the multiphase boost converter 21 (the three-phase voltage converters 21u, 21v and 21w) is configured by the motor 22 and the inverter 24 between the power line 32 and the power line 28.

The driving ECU 60 then sets the two driving phases for efficiency and heat generation (step S110). In the embodiment, the driving ECU 60 performs three-phase interleaved driving or two-phase interleaved driving during the external charging. In the three-phase interleaved driving, the switching control of the transistors T11 to T16 of the inverter 24 is performed such that the phases of the U, V and W phase currents Iu, Iv and Iw of the motor 22 are shifted 120 degrees from each other. For example, in the three-phase interleaved driving, the phases of the U, V and W phase currents Iu, Iv and Iw of the motor 22 may be shifted 120 degrees from each other by shifting the phases of carriers (e.g., triangular waves, sawtooth waves, inverse sawtooth waves, etc.) of each phase in duty control of the U phase transistors T11 and T12, the V phase transistors T13 and T14, and W phase transistors T15 and T16 of the inverter 24 by 120 degrees from each other. In the two-phase interleaved driving, the switching control of the transistors T11 to T16 of the inverter 24 is performed such that phases of the phase currents of the two phases (e.g., the V and W phase currents Iv and Iw) of the motor 22 are shifted by 180 degrees from each other. For example, in the two-phase interleaved driving, the phases of the two-phase currents of the motor 22 may be shifted by 180 degrees from each other by shifting the phase of the carriers of each phase in the duty control of the transistors of the two phases of the inverter 24 by 180 degrees from each other. The three-phase interleaved driving corresponds to the interleaved driving in the first mode of the present disclosure, and the two-phase interleaved driving corresponds to the interleaved driving in the second mode of the present disclosure. The two driving phases are the two phases of the multiphase boost converter 21 (the three-phase voltage converters 21u, 21v and 21w) that are to be driven by the two-phase interleaved driving.

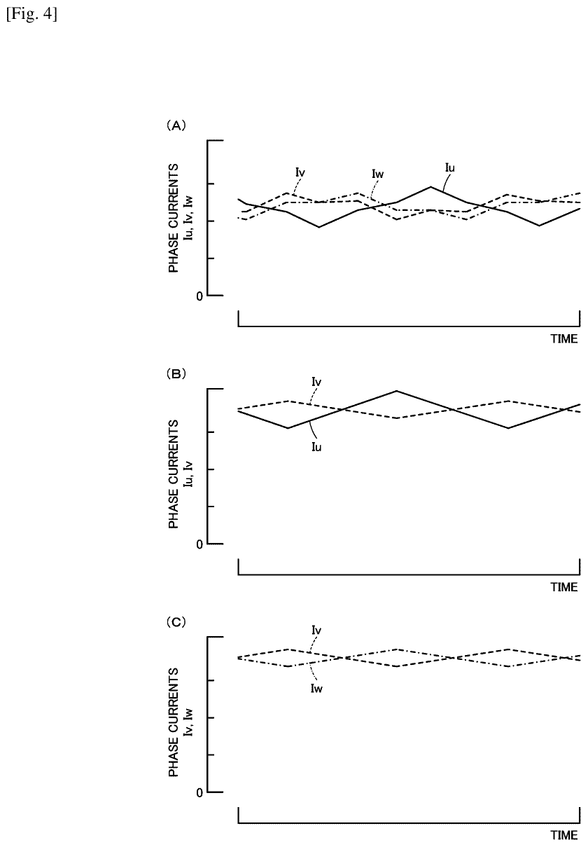

FIG. 4 is a diagram showing one example of the phase currents Iu, Iv and Iw of the motor 22. FIG. 4(A) shows one example of a case where the three-phase interleaved driving is performed. FIG. 4(B) shows one example of a case where the two-phase interleaved driving is performed with the two driving phases as the two phases with the largest discrepancy (difference) in inductance values among the three phases of the motor 22. FIG. 4(C) shows one example of a case where the two-phase interleaved driving is performed with the two driving phases as the two phases with the smallest discrepancy in the inductance values among the three phases of the motor 22. FIG. 4 shows a case where the discrepancy between the inductance values Lv and Lw of the V and W phases is minimum and the discrepancy between the inductance values Lu and Lv of the U and V phases is maximum. The ripple of the phase currents of each phase of the motor 22 depends on the inductance value. In the examples shown in FIG. 4(A), FIG. 4(B) and FIG. 4(C), the ripple (amplitude) Iru of the U phase current Iu is somewhat larger than the ripples Irv and Irw of the V and W phase currents Iv and Iw, the ripple Irw of the W phase current Irw is slightly larger than the ripple Irv of the V phase current Iv. Therefore, the ripple Ira of the sum of the phase currents Iu, Iv and Iw shown in FIG. 4(A), the ripple Irb of the sum of the phase currents Iu and Iv shown in FIG. 4(B), and the ripple Irc of the sum of the phase currents Iv and Iw shown in FIG. 4(C) are, from the highest to the lowest, the ripples Ira, Irb and Irc. The inventors have confirmed through experimentation, analysis, and machine learning that the smaller the ripple of the total current, the more the eddy current losses in the motor 22 are suppressed and the less heating value is generated in the motor 22. Based on these considerations, at step S110, the driving ECU 60 sets the two driving phases for efficiency as the two phases with the smallest discrepancy in the inductance value of the three phases of the motor 22, and sets the two driving phases for heat generation as the two phases with the largest discrepancy in the inductance value of the three phases of the motor 22.

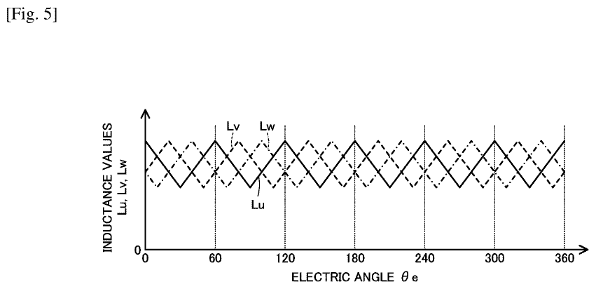

The process of step S110 is performed, for example, by applying the electric angle θe to a map of two driving phases to derive the two driving phases. The map of two driving phases is predetermined by experiment, analysis, or machine learning as the relationship between the electric angle θe of the motor 22 and the two driving phases for efficiency and heat generation. FIG. 5 is a diagram showing one example of the relationship between the electric angle θe of the motor 22 and the inductance values Lu, Lv and Lw of each phase of the motor 22. As shown, the inductance values Lu, Lv and Lw of each phase depend on the electric angle θe. The map of two driving phases is defined by considering the relationship between the electric angle Oe and the inductance values Lu, Lv and Lw. In the example shown in FIG. 5, when the electric angle Oe of the motor 22 is 59 degrees, the discrepancy in the inductance values Lv and Lw of the V and W phases is minimum, and the discrepancy in the inductance values Lu and Lv of the U and V phases is maximum. In this case, the driving ECU 60 sets the two driving phases for efficiency to the V and W phases, and sets the two driving phases for heat generation to the U and V phases.

The driving ECU 60 then sets the target power Ps* (step S120). The target power Ps* is the power to be supplied by the power supply device 82 to the neutral point 22n of the motor 22, i.e., a target value of the neutral point power. The process of step S120 is performed, for example, by setting the target power Ps* within the input limit Win of the battery 26.

The driving ECU 60 then determines whether or not the temperature rise of the battery 26 is requested (step S130), and whether or not the heating in the cabin is requested (step S132). The process of determining whether or not the temperature rise of the battery 26 is requested is performed by determining whether or not the temperature ab of the battery 26 is equal to or less than a threshold value Tbth, which is a relatively low value. For example, the threshold value Tbth is about −10° C. to 10° C. The processing of determining whether or not the heating in the cabin is requested is performed by determining whether or not a heating condition is satisfied. The heating condition is used as a condition that the heating switch 54 is turned on and the room temperature αc is lower than the set temperature αc.

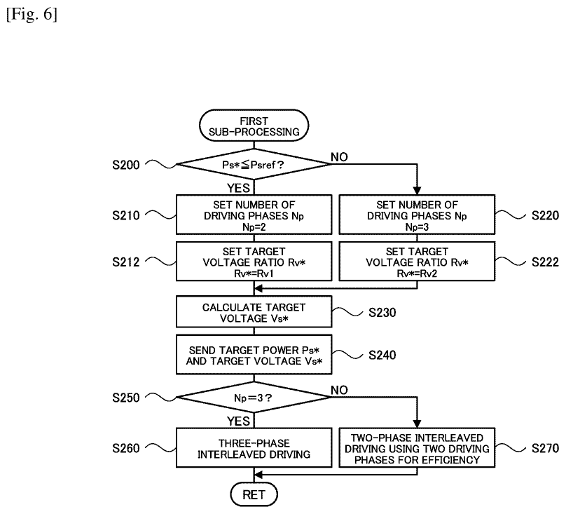

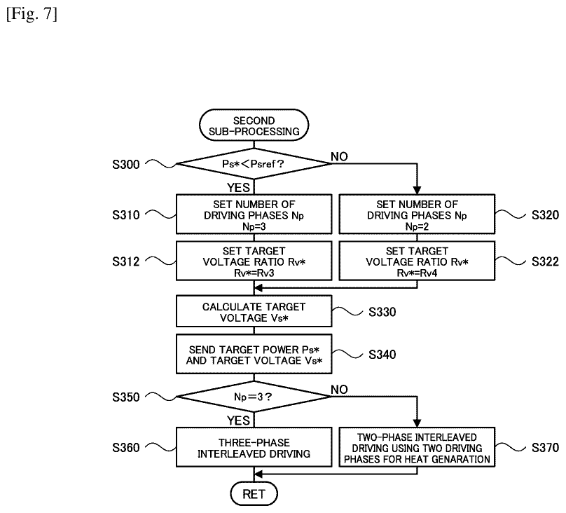

The driving ECU 60 performs the first sub-processing shown in FIG. 6 (step S140) when the driving ECU 60 determines that the temperature rise of the battery 26 is not requested at step S130 and that the heating in the cabin is not requested at step S132. On the other hand, the driving ECU 60 performs the second sub-processing shown in FIG. 7 (step S150) when the driving ECU 60 determines that the temperature rise of the battery 26 is requested at step S130 or the heating in the cabin is requested at step S132. The first sub-processing and the second sub-processing are the processes of performing the three-phase interleaved driving or the two-phase interleaved driving and transmitting the target power Ps* and the target voltage Vs* to the stand ECU 88 of the charging stand 80. The target voltage Vs* is the voltage to be applied by the power supply device 82 to the neutral point 22n of the motor 22. Details of the first sub-processing and the second sub-processing are described below.

The driving ECU 60 then determines whether or not a charging stop condition is satisfied (step S160). The charging stop condition is, for example, an OR condition, such as a condition in which the state of charge SOC of the battery 26 reaches equal to or greater than the threshold value Sth, or a condition in which the user instructs to stop charging the battery 26, and so on. The driving ECU 60 returns to step S120 when it determines that the charging stop condition is not satisfied at step S160.

The driving ECU 60 performs a stop processing (step S170) when it determines that the charging stop condition is satisfied at step S160, and then terminates this routine. In the stop processing, the driving ECU 60 stops the inverter 24 and sends a power supply stop command to the stand ECU 88. The stand ECU 88 stops the power supply device 82 upon receiving the power supply stop command. This terminates the external charging.

The following describes the processing of step S140 of the external charging control routine shown in FIG. 3, that is, the first sub-processing shown in FIG. 6. As mentioned above, the first sub-processing is performed when the driving ECU 60 determines that the temperature rise of the battery 26 is not requested at step S130 and that the heating in the cabin is not requested at step S132.

In the first sub-processing, the driving ECU 60 first determines whether or not the target power Ps* is equal to or less than the threshold value Psref (step S200). The inventors have confirmed the following through experimentation, analysis, and machine learning. As mentioned above, the eddy current loss of the motor 22 is suppressed and the heating value (temperature rise) of the motor 22 caused by the eddy current loss is suppressed when the two-phase interleaved driving is performed as compared to when the three-phase interleaved driving is performed. However, the heating value of the inverter 24 and the heating value of the motor 22 due to the copper loss of the motor 22 are larger when the two-phase interleaved driving is performed than when the three-phase interleaved driving is performed because of the current con-centration in the two driving phases when the two-phase interleaved driving is performed. The heating value of the motor 22 is sufficiently affected by the eddy current losses than by the copper losses. The heating value (heat loss) of the entire driving section, including the motor 22 and the inverter 24, is more affected by the heating value of the motor 22 (especially the heating value due to the eddy current losses) than by the heating value of the inverter 24 when the neutral point power is relatively small. Therefore, when the neutral point power is relatively small, the heating value of the entire driving section is larger and the efficiency of the external charging is lower when the three-phase interleaved driving is performed than when the two-phase interleaved driving is performed. On the other hand, the heating value of the entire driving section is more affected by the heating value of the inverter 24 than by the heating value of the motor 22 when the neutral point power is relatively high. Therefore, when the neutral point power is relatively high, the heating value of the entire driving section is larger and the efficiency of the external charging is lower when the two-phase interleaved driving is performed than when the three-phase interleaved driving is performed. The threshold value Psref is determined by experiment, analysis, or machine learning based on the specifications of the motor 22 and the inverter 24 as a boundary value between a region where the heating value of the entire driving section is larger when the three-phase interleaved driving is performed and a region where the heating value of the entire driving section is larger when the two-phase interleaved driving is performed. The threshold value Psref is, for example, several tens of kW.

The driving ECU 60 sets the number of driving phases Np to 2 (step S210) and sets the target voltage ratio Rv* of the multiphase boost converter 21 to a predetermined value Rv1 (step S212) when it determines that the target power Ps* is equal to or less than the threshold value Psref at step S200. The number of driving phases Np is the number of driving phases (three phases or two phases) to be driven by the interleaved driving of the multiphase boost converter 21 (three-phase voltage conversion sections 21u, 21v, 21w). The target voltage ratio Rv* of the multiphase boost converter 21 is defined as the voltage ratio between the target voltage of the power line 32 (the target voltage of the power supply device 82) and the voltage of the power line 28 (the voltage of the battery 26). On the other hand, the driving ECU 60 sets the number of driving phases Np to 3 (step S220) and sets the target voltage ratio Rv* of the multiphase boost converter 21 to a predetermined value Rv2 (step S222) when it determines that the target power Ps* is greater than the threshold value Psref at step S200. From the above, the driving ECU 60 performs the one with the smaller heating value (heat loss) of the entire driving section of the three-phase interleaved driving and the two-phase interleaved driving when neither the temperature rise of the battery 26 nor the heating in the cabin is requested. The predetermined values Rv1 and Rv2 are described below.

The driving ECU 60 then calculates the target voltage Vs* (step S230) and transmits the target power Ps* and the target voltage Vs* to the stand ECU 88 of the charging stand 80 (step S240). The target voltage Vs* is calculated as the product of the voltage Vb of the battery 26 and the target voltage ratio Rv* of the multiphase boost converter 21. Upon receiving the target power Ps* and the target voltage Vs*, the stand ECU 88 controls the power supply device 82 such that the output voltage Vs is equal to the target voltage Vs* and the output power Ps is equal to the target power Ps *.

Then, the driving ECU 60 determines whether the number of driving phases Np is 3 or 2 (step S250). The driving ECU 60 performs the three-phase interleaved driving (step S260) and terminates the first sub-processing when it determines that the number of driving phases Np is 3. On the other hand, the driving ECU 60 performs the two-phase interleaved driving using the two driving phases for efficiency set at step S110 (step S270) and terminates the first sub-processing when it determines that the number of driving phases Np is 2. The driving ECU 60 performs the one with the smaller heating value (heat loss) of the entire driving section of the three-phase interleaved driving and the two-phase interleaved driving when neither the temperature rise of the battery 26 nor the heating of the cabin is requested. The efficient external charging is thus possible. In addition, the driving ECU 60 uses the two driving phases for efficiency instead of the two driving phases for heat generation when two-phase interleaved driving is performed. This suppresses the eddy current loss of the motor 22 and further suppresses the heating value of the entire driving section. The duty of the transistors T11 to T16 in the three-phase interleaved driving or the two-phase interleaved driving is set based on the target voltage ratio Rv* of the multiphase boost converter 21.

The following describes the processing of step S150 of the external charging control routine shown in FIG. 3, that is, the second sub-processing shown in FIG. 7. As mentioned above, the second sub-processing is performed when the driving ECU 60 determines that the temperature rise of the battery 26 is requested at step S130 or the heating in the cabin is requested at step S132.

In the second sub-processing, the driving ECU 60 first determines whether or not the target power Ps* is less than the threshold value Psref (step S300). The driving ECU 60 sets the number of driving phases Np to 3 (step S310) and sets the target voltage ratio Rv* of the multiphase boost converter 21 to the predetermined value Rv3 (step S312) when it determines that the target power Ps* is less than the threshold value Psref. On the other hand, the driving ECU 60 sets the number of driving phases Np to 2 (step S320) and sets the target voltage ratio Rv* of the multiphase boost converter 21 to the predetermined value Rv4 (step S322) when it determines that the target power Ps* is equal to or greater than the threshold value Psref. From the above, the driving ECU 60 performs the one with the larger heating value (heat loss) of the entire driving section of the three-phase interleaved driving and the two-phase interleaved driving when at least one of the temperature rise of the battery 26 and the heating in the cabin is requested. The predetermined values Rv3 and Rv4 are described below.

The driving ECU 60 then calculates the target voltage Vs* (step S330), transmits the target power Ps* and the target voltage Vs* to the stand ECU 88 (step S340), and determines whether the number of driving phases Np is 3 or 2 (step S350), similar to steps S230 to S250 of the first sub-processing shown in FIG. 6. The driving ECU 60 performs the three-phase interleaved driving (step S360) and terminates the second sub-processing when it determines that the number of driving phases Np is 3. On the other hand, the driving ECU 60 performs the two-phase interleaved driving using the two driving phases for heat generation set at step S110 (step S370) and terminates the second sub-processing when it determines that the number of driving phases Np is 2. The driving ECU 60 performs the one with the larger heating value (heat loss) of the entire driving section of the three-phase interleaved driving and the two-phase interleaved driving when at least one of the temperature rise of the battery 26 and the heating of the cabin is requested. Thus, more heat from the motor 22 and the inverter 24 is supplied to the battery 26 by the cooling water in the cooler 40 and the air blown into the cabin is heated more by heat exchange with the heat exchanger 44 of the cooler 40. As a result, the temperature rise of the battery 26 is accelerated and/or the cabin is heated more adequately. In addition, the driving ECU 60 uses the two driving phases for heat generation instead of the two driving phases for efficiency when performing the two-phase interleaved driving. This further increases the heating value of the entire driving section.

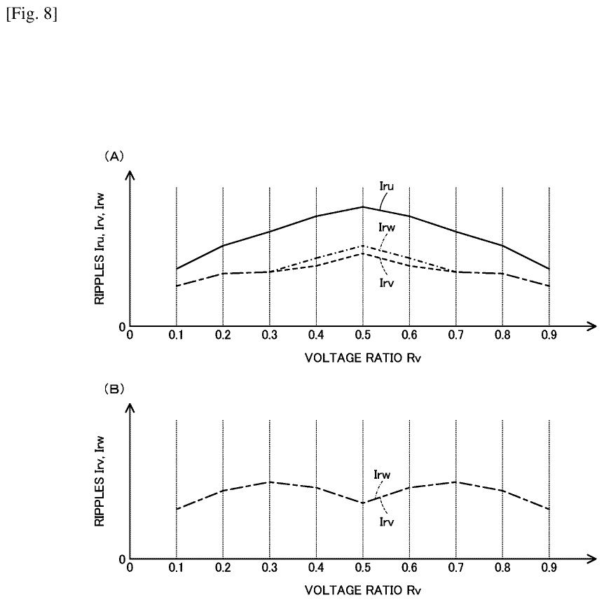

The predetermined values Rv1 to Rv4 are described in this section. FIG. 8 is a diagram showing one example of the relationship between the voltage ratio Rv of the multiphase boost converter 21 and the ripples Iru, Irv and Irw of the phase currents Iu, Iv and Iw of the motor 22. The voltage ratio Rv of the multiphase boost converter 21 is defined as the voltage ratio between the voltage of the power line 32 (the output voltage of the power supply device 82) and the voltage of the power line 28 (the voltage of the battery 26). FIG. 8(A) shows one example of the relationship when the three-phase interleaved driving is performed. FIG. 8(B) shows one example of the relationship when the two-phase interleaved driving is performed. Similar to that shown in FIG. 4, FIG. 8(A) shows the case where the discrepancy between the inductance values Lv and Lw of the V and W phases is minimum and the discrepancy between the inductance values Lu and Lv of the U and V phases is maximum. FIG. 8(B) also shows one example of the relationship when the two-phase interleaved driving is performed using the two driving phases for efficiency. When the two-phase interleaved driving is performed with the two driving phases for heat generation, it can be considered in the same way as when the two-phase interleaved driving is performed with the two driving phases for efficiency.

As shown in FIG. 8(A), the ripples Iru, Irv and Irw of the phase currents Iu, Iv and Irw of the U, V and W phases of the motor 22 are all extremely large when the voltage ratio Rv of the multiphase boost converter 21 is 0.5, and become smaller as the voltage ratio Rv of the multiphase boost converter 21 moves away from 0.5, in the case where the driving ECU 60 performs the three-phase interleaved driving. As shown in FIG. 8(B), the ripples Irv and Irw of the phase currents Iv and Iw of the V and W phases are all extremely small when the voltage ratio Rv of the multiphase boost converter 21 is 0.5, and are also extremely large when the voltage ratio Rv of the multiphase boost converter 21 is about 0.3 or 0.7. The inventors have confirmed through experimentation, analysis, and machine learning that the larger the ripples of the phase currents of each phase of the motor 22, the larger the heating value (heat loss) of the entire driving section.

Based on these considerations, the predetermined value Rv1 is used, for example, 0.5, and the predetermined value Rv2 is used, for example, 0.33 or 0.67. From the above, the heating value (heat loss) of the entire driving section is suppressed in the three-phase interleaved driving or the two-phase interleaved driving when neither the temperature rise of the battery 26 nor the heating in the cabin is required. As a result, the efficient external charging is possible.

The predetermined value Rv3 is used, for example, 0.5, and the predetermined value Rv4 is used, for example, 0.33 or 0.67. From the above, the heating value (heat loss) of the entire driving section in the three-phase interleaved driving or the two-phase interleaved driving is increased when at least one of the temperature rise of the battery 26 and the heating in the cabin is requested. As a result, the temperature rise of the battery 26 is accelerated and/or the cabin is heated more adequately.

In the driving apparatus 20 of the embodiment described above, the driving ECU 60 performs the three-phase interleaved driving (the driving of the inverter 24 in the first mode) or the two-phase interleaved driving (the driving of the inverter 24 in the second mode) during the external charging, where the power supplied by the power supply device 82 to the neutral point 22n of the motor 22 of the charging stand 80 is supplied to the battery 26 with voltage conversion by the multiphase boost converter 21 (the motor 22 and the inverter 24). The external charging is performed more appropriately.

Specifically, the driving ECU 60 performs the two-phase interleaved driving when the target power Ps* is equal to or less than the threshold value Psref, and performs the three-phase interleaved driving when the target power Ps* is greater than the threshold value Psref, in the case that neither the temperature rise of the battery 26 nor the heating of the cabin is requested. In this configuration, the one with the smaller heating value (heat loss) of the entire driving section of the three-phase interleaved driving and the two-phase interleaved driving is performed. As a result, the efficient external charging is possible. In addition, the driving ECU 60 uses the two driving phases for efficiency instead of the two driving phases for heat generation when the two-phase interleaved driving is performed in the case where neither the temperature rise of the battery 26 nor the heating in the cabin is requested. This further suppresses the heating value of the entire driving section.

The driving ECU 60 performs the three-phase interleaved driving when the target power Ps* is less than the threshold value Psref, and performs the two-phase interleaved driving when the target power Ps* is equal to or greater than the threshold value Psref, in the case where at least one of the temperature rise of the battery 26 and the heating in the cabin is requested. In this configuration, the one with the larger heating value (heat loss) of the entire driving section of the three-phase interleaved driving and the two-phase interleaved driving is performed. As a result, the temperature rise of the battery 26 is accelerated and/or the cabin is heated more adequately. In addition, the driving ECU 60 uses the two driving phases for heat generation instead of the two driving phases for efficiency when performing the two-phase interleaved driving in the case where at least one of the temperature rise of the battery 26 and the heating in the cabin is requested. This further increases the heating value of the entire driving section.

In the driving apparatus 20 of the embodiment, the driving ECU 60 sets the target voltage ratio Rv* of the multiphase boost converter 21 based on whether the temperature rise of the battery 26 is requested, and whether the heating of the cabin is requested, and the number of driving phases Np in the interleaved driving, and transmits the target voltage Vs* based on the voltage Vb of the battery 26 and the target voltage ratio Rv* to the stand ECU 88, during the external charging. The stand ECU 88 controls the power supply device 82 such that the output voltage Vs is equal to the target voltage Vs*. This enables the external charging to be performed more appropriately.

Specifically, the driving ECU 60 sets the target voltage ratio Rv* of the multiphase boost converter 21 such that the ripples of the phase currents of each phase of the motor 22 in the three-phase interleaved driving and the two-phase interleaved driving are small when neither the temperature rise of the battery 26 nor the heating in the cabin is requested. Thus, the heating value (heat loss) of the entire driving section is suppressed. As a result, the efficient external charging is possible.

The driving ECU 60 sets the target voltage ratio Rv* of the multiphase boost converter 21 such that the ripples of the phase currents of each phase of the motor 22 in the three-phase interleaved driving and the two-phase interleaved driving are large when at least one of the temperature rise of the battery 26 and the heating in the cabin is requested. In this configuration, the heating value of the entire driving section is increased. As a result, the temperature rise of the battery 26 is accelerated and/or the cabin is heated more adequately.

In the embodiment described above, the driving ECU 60 sets the two driving phases for efficiency and heat generation based on the electric angle θe of the motor 22 in the external charging control routine shown in FIG. 3. However, the driving ECU 60 may set the two driving phases for efficiency and heat generation as follows. The driving ECU 60 turns on the transistors T12, T14 and T16 of the inverter 24 and sends a test voltage command to the stand ECU 88. The stand ECU 88 controls the power supply device 82 to apply the test voltage (e.g., a constant voltage for a predetermined time) to the neutral point 22n of the motor 22. This causes phase currents to flow in each phase of the motor 22. The driving ECU 60 detects the phase current change rates ΔIu, ΔIv and ΔIw, which are the changes in the phase currents Iu, Iv and Iw of each phase of the motor 22 per unit time, and sets the two driving phases for efficiency and for heat generation based on the detected phase current change rates ΔIu, ΔIv and ΔIw. The phase current change rates ΔIu, ΔIv and ΔIw depend on the inductance values Lu, Lv and Lw of each phase. Therefore, the driving ECU 60 sets the two driving phases for efficiency to the two phases with the smallest discrepancy in the phase current change rates of each phase of the motor 22, and sets the two driving phases for heat generation to the two phases with the largest discrepancy in the phase current change rates of each phase of the motor 22. In this case, the driving apparatus 20 and the charging stand 80 simultaneously flow the phase currents to the three phases of the motor 22 and detect the phase current change rates ΔIu, ΔIv and ΔIw of each phase. Alternatively, the driving apparatus 20 and the charging stand 80 may sequentially flow the phase current to each phase of the motor 22 and detect the phase current change rates ΔIu, ΔIv and ΔIw of each phase.

In the embodiment described above, the driving ECU 60 performs the first sub-processing shown in FIG. 6 or the second sub-processing shown in FIG. 7 based on whether or not the temperature rise of the battery 26 is requested and whether or not the heating in the cabin is requested in the external charging control routine shown in FIG. 3. However, the driving ECU 60 may perform the first sub-processing or the second sub-processing based on only one of whether or not the temperature rise of the battery 26 is requested and whether or not the heating in the cabin is requested.

In the embodiment described above, the driving ECU 60 sets the number of driving phases Np in the interleaved driving based on whether or not the temperature rise of the battery 26 is requested, whether or not the heating in the cabin is requested, and the target power Ps* in the external charging control routine shown in FIG. 3 (the first sub-process shown in FIG. 6 and the sub-process shown in FIG. 7). However, the driving ECU 60 may set the number of driving phases Np in the interleaved driving based solely on the target power Ps*. In this case, the driving ECU 60 may set the number of driving phases Np to 2 when the target power Ps* is equal to or less than the threshold Psref, and may set the number of driving phases Np to 3 when the target power Ps* is greater than the threshold Psref.

In the embodiment described above, the driving ECU 60 sets the target voltage ratio Rv* based on whether or not the temperature rise of the battery 26 is requested, whether or not the heating in the cabin is requested, and the number of driving phases Np in the interleaved driving in the external charging control routine shown in FIG. 3 (the first sub-process shown in FIG. 6 and the sub-process shown in FIG. 7). However, the driving ECU 60 may set the target voltage ratio Rv* based solely on the number of driving phases Np of the interleaved driving. In this case, for example, the driving ECU 60 may set the target voltage ratio Rv* to the predetermined value Rv1 or Rv2. The target voltage ratio Rv* may be a predetermined constant value.

In the embodiment described above, the driving ECU 60 uses the two driving phases for efficiency or heat generation in the two-phase interleaved driving based on whether or not the temperature rise of the battery 26 is requested, and whether or not the heating in the cabin is requested in the external charging control routine shown in FIG. 3 (the first sub-process shown in FIG. 6 and the sub-process shown in FIG. 7). However, the driving ECU 60 may always use the two driving phases for efficiency or the two driving phases that are predetermined.

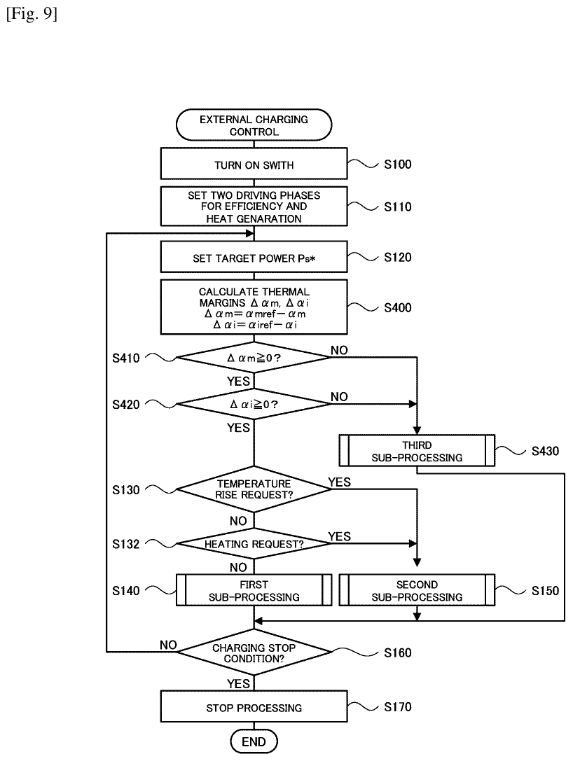

In the embodiment described above, the driving ECU 60 performs the external charging control routine shown in FIG. 3. However, the driving ECU 60 may perform the external charging control routine shown in FIG. 9. The external charging control routine shown in FIG. 9 differs from the external charging control routine shown in FIG. 3 in that steps S400 to S430 are added.

In the external charging control routine shown in FIG. 9, the driving ECU 60 calculates the thermal margins Δαm and Δαi of the motor 22 and the inverter 24 (step S400) after setting the target power Ps* at step S120. The thermal margin Δαm of the motor 22 is calculated as a value obtained by subtracting the temperature am of the motor 22 from the predetermined temperature αmref. The thermal margin Δαi of the inverter 24 is calculated as a value obtained by subtracting the temperature ai of the inverter 24 from the predetermined temperature αiref. The predetermined temperature αmref is determined as a temperature that is somewhat lower than the superheat temperature of the motor 22, for example, 80° C. to 120° C. is used. The predetermined temperature αiref is determined as a temperature that is somewhat lower than the superheat temperature of the inverter 24, for example, 80° C. to 120° C. is used. The smaller the values of the thermal margins Δαm and Δαi of the motor 22 and the inverter 24, respectively, the more severe the motor 22 and the inverter 24 are thermally.

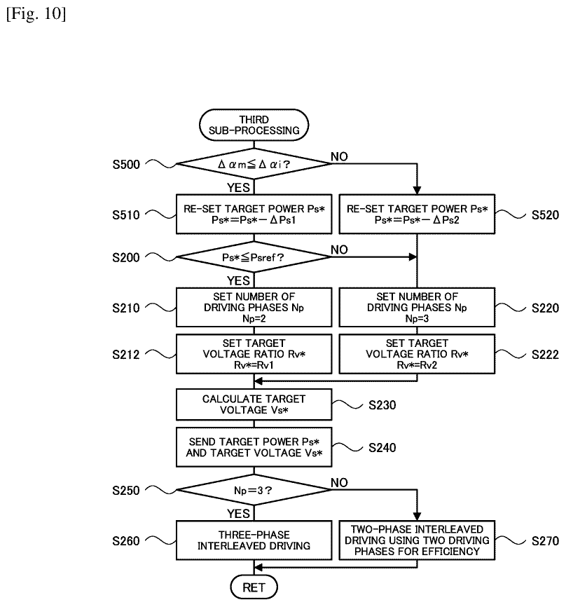

The driving ECU 60 then determines whether the thermal margin Δαm of the motor 22 is equal to or greater than 0 (step S410) and whether the thermal margin Δαi of the inverter 24 is equal to or greater than the value 0 (step S420). The driving ECU 60 proceeds to step S130 when it determines that the thermal margin Δαm of the motor 22 is equal to or greater than 0 and the thermal margin Δαi of the inverter 24 is equal to or greater than 0. On the other hand, the driving ECU 60 performs the third sub-processing shown in FIG. 10 (step S430) and proceeds to step S160 when it determines that the thermal margin Δαm of the motor 22 is less than 0 or that the thermal margin Δαi of the inverter 24 is less than 0.

The following describes the third sub-processing shown in FIG. 10. The third sub-processing shown in FIG. 10 differs from the first sub-processing shown in FIG. 6 in that steps S500 to S520 are added.

In the third sub-processing shown in FIG. 10, the driving ECU 60 first determines whether the thermal margin Δαm of the motor 22 is equal to or less than the thermal margin Δαi of the inverter 24 (step S500). The driving ECU 60 re-sets the target power Ps* (step S510) and proceeds to step S200 when it determines that the thermal margin Δαm of the motor 22 is equal to or less than the thermal margin Δαi of the inverter 24. The processing of step S510 is performed by setting the new target power Ps* to the value obtained by subtracting the correction value ΔPs1 from the target power Ps* set at step S120. The correction value ΔPs1 may be a constant value, or a value that increases as the thermal margin Δαm of the motor 22 decreases (increasing absolute value in the negative range).

The processing of step S510 results in the smaller neutral point power. This suppresses the temperature rise of the motor 22 and the inverter 24. Further, the driving ECU 60 performs the two-phase interleaved driving when the target power Ps* is equal to or less than the threshold value Psref, and performs the three-phase interleaved driving when the target power Ps* is greater than the threshold value Psref, as in the case where neither the temperature rise of the battery 26 nor the heating in the cabin is requested. This enables the suppression of the heating value of the motor 22 due to the eddy current loss of the motor 22 when the target power Ps* is equal to or less than the threshold value Psref, and the suppression of the heating value of the motor 22 due to the copper loss of the motor 22 when the target power Ps* is greater than the threshold value Psref. In addition, the driving ECU 60 uses the two driving phases for efficiency and sets the target voltage ratio Rv* of the multiphase boost converter 21 to the predetermined value Rv1, as in the case where neither the temperature rise of the battery 26 nor the heating in the cabin is requested. This further suppresses the heating value (heat loss) of the entire driving section.

The driving ECU 60 re-sets the target power Ps* (step S520) and proceeds to step S220 when it determines that the thermal margin Δαm of the motor 22 is greater than the thermal margin Δαi of the inverter 24 at step S500. The processing of step S520 is performed by setting the new target power Ps* to the value obtained by subtracting the correction value ΔPs2 from the target power Ps* set at step S120. The correction value ΔPs2 may be a constant value (e.g., the same value as the correction value ΔPs1) or a value that increases as the thermal margin Δαi of the inverter 24 decreases (increasing absolute value in the negative range).

This processing results in the smaller neutral point power. This suppresses the temperature rise of the motor 22 and the inverter 24. The driving apparatus 20 performs the three-phase interleaved driving when the inverter 24 is thermally more severe than the motor 22. This enables the further temperature rise of the inverter 24 to be suppressed compared to when the two-phase interleaved driving is performed. In addition, the driving ECU 60 uses the two driving phases for efficiency and sets the target voltage ratio Rv* of the multiphase boost converter 21 to the predetermined value Rv2, as in the case where neither the temperature rise of the battery 26 nor the heating in the cabin is requested. This further suppresses the heating value (heat loss) of the entire driving section.

In the external charging control routine shown in FIG. 9, the driving ECU 60 performs the third sub-processing shown in FIG. 10 when it determines that the thermal margin Δαm of the motor 22 is less than 0 or when it determines that the thermal margin Δαi of the inverter 24 is less than 0. However, the driving ECU 60 may perform the processing of step S510 or later of the third sub-processing only when it determines that the thermal margin Δαm of the motor 22 is less than 0. Also, the driving ECU 60 may perform the processing of step S520 or later of the third sub-processing only when it determines that the thermal margin Δαi of the inverter 24 is less than 0.

In the sub-processing shown in FIG. 10, the driving ECU 60 re-sets the target power Ps* when it determines that the thermal margin Δαm of the motor 22 is equal to or less than the thermal margin Δαi of the inverter 24, and when it determines that the thermal margin Δαm of the motor 22 is greater than the thermal margin Δαi of the inverter 24, respectively. However, the driving ECU 60 may re-set the target power Ps* only when it determines that the thermal margin Aam of the motor 22 is equal to or less than the thermal margin Δαi of the inverter 24. The driving ECU 60 may also re-set the target power Ps* only when it determines that the thermal margin Δαm of the motor 22 is greater than the thermal margin Δαi of the inverter 24. Further, the driving ECU 60 may not re-set the target power Ps* when it determines that the thermal margin Δαm of the motor 22 is equal to or less than the thermal margin Δαi of the inverter 24, or when it determines that the thermal margin Δαm of the motor 22 is greater than the thermal margin Δαi of the inverter 24, in any of these cases.

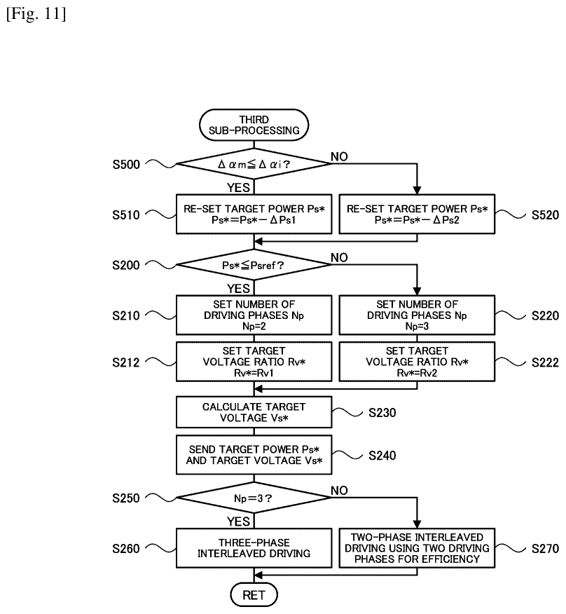

The third sub-processing shown in FIG. 10 may be replaced by the third sub-processing shown in FIG. 11. The third sub-processing shown in FIG. 11 differs from the third sub-processing shown in FIG. 10 in that after the processing of step S520, processing proceeds to step S200 instead of step S220.

In the embodiments described above, the driving ECU 60 sets the target power Ps* at step S120 of the external charging control routine shown in FIG. 3 and FIG. 9. In addition, the driving ECU 60 uses the target power Ps* at step S200 of the first sub-processing shown in FIG. 6, at step S300 of the second sub-processing shown in FIG. 7, and at step S200 of the third sub-processing shown in FIG. 11. In addition, the driving ECU 60 re-sets the target power Ps* at steps S510 and S520 shown in FIG. 10 and FIG. 11. However, the target power Ps* may be replaced by the target current Is*. The target current Is* is the current that is to be supplied by the power supply device 82 to the neutral point 22n of the motor 22. When the target current Is* is used, it can be considered in the same way as when the target power Ps* is used. The neutral point power or the neutral point current supplied by the power supply device 82 to the neutral point 22n of the motor 22 may be used instead of the target power Ps* or the target current Is*, at steps S200, 300. The neutral point power or the neutral point current may be used as the output power Ps or the output current Is of the power supply device 82, respectively.

In the embodiment described above, the driving ECU 60 performs the three-phase interleaved driving or the two-phase interleaved driving during the external charging. However, in addition to or instead thereof, the driving ECU 60 may perform the three-phase interleaved driving or the two-phase interleaved driving during the external power supply. The external power supply is the power supply to the outside of the driving apparatus 20 (battery electric vehicle 10) using power from the battery 26. In the external power supply, the power from the battery 26 is supplied to the outside of the driving apparatus 20 with the voltage conversion by the multiphase boost converter 21 (the motor 22 and the inverter 24). The determination of whether the three-phase interleaved driving and the two-phase interleaved driving is to be performed can be considered in the same way as the determination during the external charging.

In the embodiment described above, the driving ECU 60 performs the three-phase interleaved driving or the two-phase interleaved driving during the external charging. However, the driving ECU 60 may control the inverter 24 in the first mode of driving all three phases of the inverter 24, or in the second mode of driving two of the three phases of the inverter 24, during the external charging. For example, the driving ECU 60 may perform the switching control of the transistors T11 to T16 of the inverter 24 such that the phase currents of each phase of the motor 22 are in-phase in the first mode or in the second mode. During the external power supply, it can be considered in the same way as during the external charging.

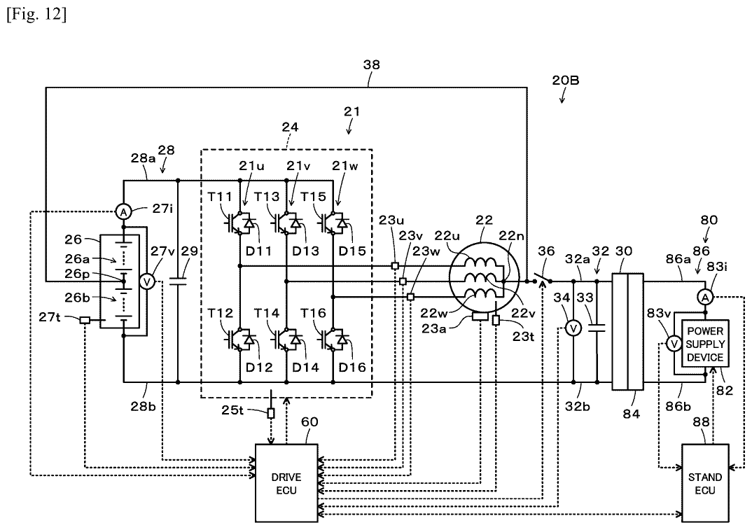

In the embodiments described above, the battery electric vehicle 10 includes the driving apparatus 20. However, as shown in FIG. 12, the battery electric vehicle 10 may include the driving apparatus 20B. The driving apparatus 20B differs from the driving apparatus 20 in that it further includes a power line 38. In the driving apparatus 20B, the battery 26 is configured with a first battery 26a and a second battery 26b connected in series with each other. The first battery 26a and the second battery 26b are each configured with a plurality of battery cells connected in series with each other. The power line 38 is connected to the neutral point 22n of the motor 22 and to a connection point 26p between the first battery 26a and the second battery 26b. In this driving apparatus 20B, the driving ECU 60 drives the inverter 24 to increase the temperature of the first battery 26a and the second battery 26b when the external charging is not being performed.

In the embodiment described above, each battery cell of the battery 26 of the driving apparatus 20 is configured as a lithium ion rechargeable battery, respectively. However, each battery cell may be configured as a nickel hydrogen rechargeable battery, respectively.

In the embodiments described above, the power storage device is the battery 26. However, the power storage device may also be a capacitor.

In the embodiment described above, the heater 50 of the driving apparatus 20 uses the cooling water of the cooler 40 (the cooling water heated by the motor 22 and the inverter 24) as a heat source to heat the cabin. However, the heater 50 is not limited to this configuration as long as the heater 50 uses the motor 22 and the inverter 24 as a heat source to heat in the cabin.

In the embodiments described above, the driving apparatus 20 is mounted on the battery electric vehicle 10. However, the driving apparatus 20 may be mounted on a hybrid electric vehicle or on a fuel cell electric vehicle, on a moving vehicle other than a vehicle, or on construction equipment that is not moving.

The following describes the correspondence relationship between the primary elements of the above embodiment and the primary elements of the disclosure described in Summary. In the embodiment, the motor 22 corresponds to the “motor”, the battery 26 corresponds to the “power storage device”, the inverter 24 corresponds to the “inverter”, and the driving ECU 60 corresponds to the “controller”.

The correspondence relationship between the primary elements of the embodiment and the primary elements of the disclosure, regarding which the problem is described in Summary, should not be considered to limit the elements of the disclosure, regarding which the problem is described in Summary, since the embodiment is only illustrative to specifically describes the aspects of the disclosure, regarding which the problem is described in Summary. In other words, the disclosure, regarding which the problem is described in Summary, should be interpreted on the basis of the description in the Summary, and the embodiment is only a specific example of the disclosure, regarding which the problem is described in Summary.

The aspect of the disclosure is described above with reference to the embodiment. The disclosure is, however, not limited to the above embodiment but various modifications and variations may be made to the embodiment without departing from the scope of the disclosure.

### INDUSTRIAL APPLICABILITY

The technique of the disclosure is applicable to the manufacturing industries of the driving apparatus and so on.

1. A driving apparatus comprising: a motor with a three-phase coil; a power storage device; and an inverter configured to convert direct current power from the power storage device into three-phase alternating current power and to supply the three-phase alternating current power to the motor,
wherein the driving apparatus is programmed to perform the first mode of driving all three phases of the inverter, or the second mode of driving two of the three phases of the inverter, during at least one of external charging, in which power supplied from an external power source device to the neutral point to which the three-phase coil is connected is supplied to the power storage device with voltage conversion by the motor and the inverter, and external power supply, in which power from the power storage device is supplied to the outside of the driving apparatus via the neutral point with voltage conversion by the inverter and the motor.

2. The driving apparatus according to claim 1,
wherein the driving apparatus is configured to perform the first mode or the second mode based on at least one of information related to the motor, information related to the inverter, information related to the power storage device, information related to the neutral point, and information related to the external environment.

3. The driving apparatus according to claim 2,
wherein the driving apparatus is programmed to perform the interleaved driving in the second mode when a supply-related value relating to the power or the current supplied to the neutral point from the external power source device is equal to or less than a supply threshold value, and to perform the interleaved driving in the first mode when the supply-related value is greater than the supply threshold value.

4. The driving apparatus according to claim 3, further comprising:
a cooler configured to circulate a cooling medium to the motor, the inverter, and the power storage device,
wherein the driving apparatus is programmed to perform the interleaved driving in the first mode when a temperature rise of the power storage device is requested and the supply-related value is less than the supply threshold value, and the driving apparatus is programmed to perform the interleaved driving in the second mode when the temperature rise of the power storage device is requested and the supply-related value is equal to or greater than the supply threshold value.

5. The driving apparatus according to claim 3, further comprising:
a heater configured to use the motor and the inverter as a heat source to heat a cabin of a vehicle,
wherein the driving apparatus is programmed to perform the interleaved driving in the first mode when heating in the cabin is requested and the supply-related value is less than the supply threshold value, and the driving apparatus is programmed to perform the interleaved driving in the second mode when the heating in the cabin is requested and the supply-related value is equal to or greater than the supply threshold value.

6. The driving apparatus according to claim 2,
wherein the driving apparatus is programmed to perform the interleaved driving in the first mode when a temperature of the inverter is greater than a second temperature threshold value.

7. The driving apparatus according to claim 2,
wherein the driving apparatus is programmed to perform the interleaved driving in the first mode when a temperature of the motor is greater than a first temperature threshold value and a temperature of the inverter is greater than a second temperature threshold value and the inverter is thermally more severe than the motor.

8. The driving apparatus according to claim 2,
the driving apparatus is programmed to instruct the external power source device to limit the power or current from the external power source device to the neutral point when a temperature of the motor is greater than a first temperature threshold value and/or a temperature of the inverter is greater than a second temperature threshold value, compared to when the temperature of the motor is equal to or less than the first temperature threshold value and the temperature of the inverter is equal to or less than the second temperature threshold value.

9. The driving apparatus according to claim 1,
wherein the driving apparatus is programmed to perform the interleaved driving in the first mode or the second mode,
wherein the driving apparatus is programmed to perform the interleaved driving using two driving phases, which are the two phases with the smallest discrepancy in inductance values among the three phases, in the second mode.

10. The driving apparatus according to claim 9, further comprising:
a cooler configured to circulate a cooling medium to the motor, the inverter, and the power storage device,
wherein the driving apparatus is programmed to perform the interleaved driving using the two driving phases, which are the two phases with the largest discrepancy in the inductance values among the three phases, in the second mode when a temperature rise of the power storage device is requested.

11. The driving apparatus according to claim 9, further comprising:
a heater configured to use the motor and the inverter as a heat source to heat a cabin of the vehicle,
wherein the driving apparatus is programmed to perform the interleaved driving using the two driving phases, which are the two phases with the largest discrepancy in the inductance values among the three phases, in the second mode when heating in the cabin is requested.

12. The driving apparatus according to claim 9,
wherein the driving apparatus is programmed to set the two driving phases based on a rotational position of a rotor of the motor.

13. The driving apparatus according to claim 9,
wherein the driving apparatus is programmed to set the two driving phases based on an amount of change per unit time in a phase current of each phase of the motor when a test current flows to each phase of the motor.

14. The driving apparatus according to claim 1,
wherein the driving apparatus is programmed to set a target voltage ratio based on which one of the first mode and the second mode is selected, and to instruct the external power source device to apply a target voltage based on a voltage of the power storage device and the target voltage ratio to the neutral point from the external power source device.

15. The driving apparatus according to claim 14, further comprising:
a cooler configured to circulate a cooling medium to the motor, the inverter, and the power storage device,
wherein the driving apparatus is programmed to set the target voltage ratio based on which one of the first mode and the second mode is selected and whether or not temperature rise of the power storage device is requested.

16. The driving apparatus according to claim 14, further comprising:
a heater configured to use the motor and the inverter as a heat source to heat a cabin of the vehicle,
wherein the driving apparatus is programmed to set the target voltage ratio based on which one of the first mode and the second mode is selected and whether or not heating in the cabin is requested.
